(19) United States
(12) Patent Application Publication
(10) Pub. No.: US 2024/0006259 A1
(43) Pub. Date: Jan. 4, 2024

(54) INTEGRATED CIRCUIT WITH INDUCTOR IN MAGNETIC PACKAGE

(71) Applicant: TEXAS INSTRUMENTS INCORPORATED, Dallas, TX (US)

(72) Inventors: Hidetoshi Inoue, TOCHIGI-KEN (JP); Kenji Otake, Tokyo (JP); Yuki Sato, TAKATSU (JP); Takafumi Ando, Beppu (JP); Jeffrey Morroni, PARKER, TX (US); Anton Winkler, KIRCHDORF AN DER AMPER (DE); Yi Yan, San Jose, CA (US)

(21) Appl. No.: 17/852,979

(22) Filed: Jun. 29, 2022

(51) Int. Cl. H01L 23/29; H01L 23/00; H01L 23/31; H01L 25/16; H01L 49/02; H01L 21/56; H01F 27/32; H01F 41/00

(52) U.S. Cl. CPC H01L 23/295; H01L 24/16; H01L 23/3128; H01L 25/165; H01L 28/10; H01L 2224/81447; H01L 24/81; H01L 21/561; H01F 27/327; H01F 41/005; H01L 2224/16227; H01L 28/40

(57) ABSTRACT

In one example, an integrated circuit comprises: a substrate; a semiconductor die; metal interconnects, the semiconductor die being mounted to the substrate via the metal interconnects; an inductor mounted to the substrate; and a magnetic material encapsulating the semiconductor die, the inductor, and the metal interconnects, the magnetic material including: coated metal particles, which are coated with a first insulation material; and a second insulation material, in which the coated metal particles are suspended.

### BACKGROUND

An inductor can store energy in a magnetic field when electric current flows through it, and can provide an electric current by discharging the stored energy. Inductor can have many applications, such as proximity sensing, energy storage, actuation, power transmission, and filtering. The inductor may be coupled to or can be part of an integrated circuit, which can include circuitries that operate with the inductor to support those applications. In some examples, the inductor and the circuitries can be enclosed in an integrated circuit package, which can reduce the footprint of the integrated circuit and shorten the interconnects between the inductor and the circuitries.

### SUMMARY

An integrated circuit comprises: a substrate, a semiconductor die, metal interconnects, and inductor, and a magnetic material. The semiconductor die is mounted to the substrate via the metal interconnects. The inductor is mounted to the substrate. The magnetic material encapsulates the semiconductor die, the inductor, and the metal interconnects, the magnetic material including: coated metal particles, which are coated with a first insulation material; and a second insulation material, in which the coated metal particles are suspended.

A method comprises: mounting semiconductor dies to a substrate, and mounting inductors to the substrate. The method further comprises depositing a magnetic material on the semiconductor dies and the inductors, the magnetic material including: coated metal particles, which are coated with a first insulation material; and a second insulation material, in which the coated metal particles are suspended. The method further comprises molding the magnetic material, and dicing the magnetic material and the substrate to form integrated circuits including respective semiconductor dies and inductors.

### BRIEF DESCRIPTION OF THE DRAWINGS

FIGS. 1A and 1B are schematic diagrams of an example integrated circuit.

FIG. 2A, FIG. 2B, FIGS. 3A-3C, and FIGS. 4A-4C are schematic diagrams of examples of an integrated circuit.

FIG. 5A, FIG. 5B, and FIG. 5C are schematic diagrams illustrating the structure of an example magnetic material of an encapsulation package.

FIG. 6A and FIG. 6B are schematic diagrams illustrating the structure of another example magnetic material of an encapsulation package.

FIG. 7 is a schematic diagram illustrating the structure of another example magnetic material of an encapsulation package.

FIG. 8 is a schematic diagram illustrating the structure of another example magnetic material of an encapsulation package.

FIG. 9 is a flowchart of an example method of fabricating an integrated circuit.

FIG. 9 is a flowchart of an example method of creating a magnetic material.

FIG. 10 is a schematic diagram that illustrate various operations of the example method of FIG. 9.

FIG. 11 is a flowchart of an example method of fabricating an integrated circuit.

FIGS. 12A through 12G are schematic diagrams that illustrate various operations of the example method of FIG. 11.

### DETAILED DESCRIPTION

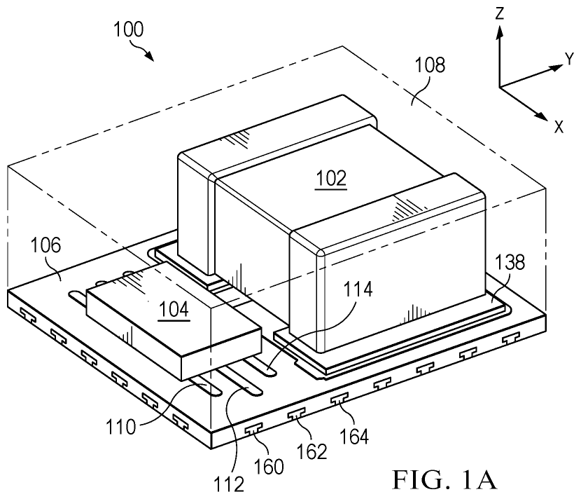

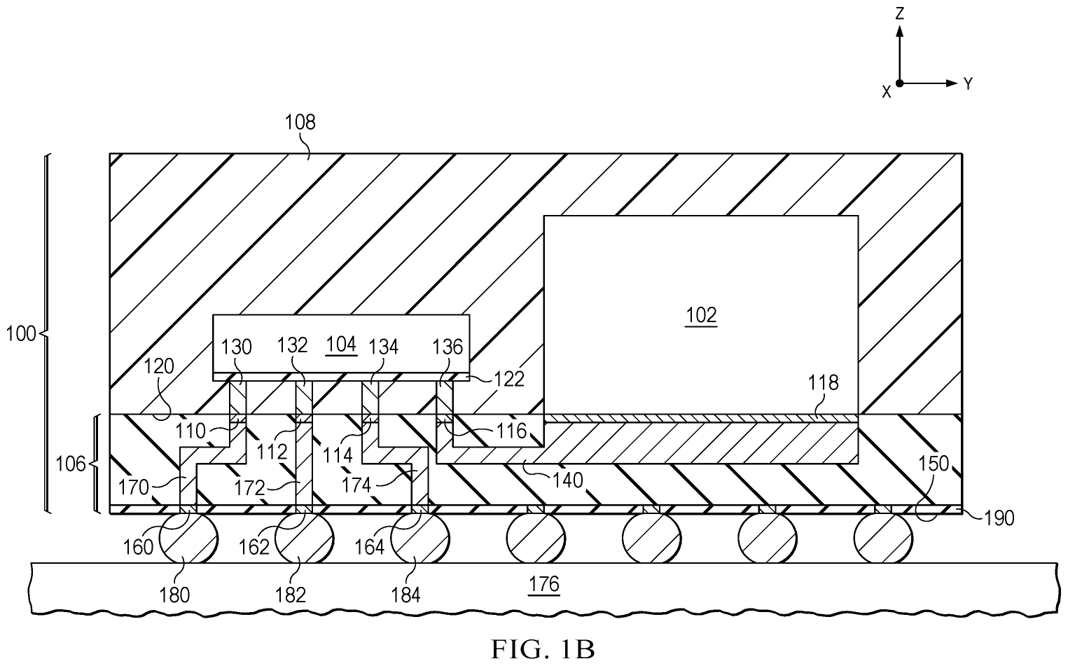

FIG. 1A and FIG. 1B are schematic diagrams that illustrate an example integrated circuit 100. FIG. 1A and FIG. 1B illustrate, respectively, a perspective view and a side view of integrated circuit 100. Referring to FIG. 1A and FIG. 1B, integrated circuit 100 can include an inductor 102 and a semiconductor die 104 mounted to a package substrate 106 and encapsulated in an encapsulation package 108. Inductor 102 can include metal coils surrounding a core. Examples of an inductor core can include an air core, a ferrite core, or a metal particle core. The inductor 102 can also be a molded inductor, in which the coils and the core can be encapsulated in a package made of a molding compound, such as a magnetic molding compound (MMC) having metallic particles (e.g., iron particles) and an insulation material (e.g., a polymer resin) in which the metallic particles are suspended. Encapsulation package 108 can shield the coils and the core and increase the magnetic field density, which can improve the efficiency of inductor 102 in converting between electrical and magnetic energies. Also, encapsulation package 108 can include a molding compound, such as an epoxy molding compound (EMC), that can electrically insulate inductor 102 and semiconductor die 104 from external electrical signals, such as noise signals and electrostatic signals.

Semiconductor die 104 and inductor 102 can form a system to support a particular application, such as proximity sensing, energy storage, actuation, power transmission, and filtering. For example, integrated circuit 100 can include a proximity sensor, in which semiconductor die 104 can include an oscillator and a sensing circuit. The oscillator can drive inductor 102 with an oscillating current signal, and the sensing circuit can sense the frequency of the current signal. A metal object approaching inductor 102 can change the inductance of inductor 102, which can change the frequency of the current signal. The sensing circuit can detect the metal object by detecting the frequency change. As another example, integrated circuit 100 can include a switch-mode power converter to transmit power from a power source to a load. In such example, inductor 102 can provide energy storage, and semiconductor die 104 can include switches to charge and discharge the inductor 102 to set the voltage across the load.

Also, package substrate 106 can provide mechanical support to inductor 102 and semiconductor die 104, and provide electrical connections between the inductor and the semiconductor die, and electrical connections to between integrated circuit 100 and an external device. For example, package substrate 106 can include an electrical insulation material, such as a polymer, an Ajinomoto Build-up Film (ABF), or a ceramic material. Package substrate 106 can also include metal pads 110, 112, 114, 116, and 118, which can be Copper pads, on a surface 120 to which inductor 102 and semiconductor die 104 are mounted.

Also, semiconductor die 104 can include a passivation layer 122, which can be coupled to metal pads 110, 112, 114, and 116 via respective metal interconnects 130, 132, 134, and 136. Each pad can be coupled to a respective metal interconnect via a solder layer. Passivation layer 122 can insulate circuitries in semiconductor die 104 from metal interconnects 130, 132, 134, and 136. Metal interconnects 130 through 136 can include, for example, Copper pillars, solder bumps, and under bump metallization (UBM) interconnects. Also, inductor 102 can be coupled to metal pad 118 via a solder layer. Package substrate 106 can include metal interconnects on or under surface 120 to provide electrical connections between inductor 102 and semiconductor die 104, such as metal interconnect 140 between metal pads 116 and 118.

Package substrate 106 can also include metal pads on a surface 150 opposite to surface 120, such as metal pads 160, 162, and 164 which can include Copper pads or pads made of other metals (e.g., Silver or Palladium). Package substrate 106 can also include metal interconnects, such as Copper interconnects, to provide electrical connections between metal pads on the opposite surfaces. For example, package substrate 106 can include metal interconnect 170 between metal pads 110 and 160, metal interconnect 172 between metal pads 112 and 162, and metal interconnect 174 between metal pads 114 and 164. The metal pads on surface 150 and the interconnects can provide electrical connections between an external device and integrated circuit 100. For example, metal pads 160, 162, and 164 can be coupled to a printed circuit board (PCB) 176 via respective solder balls 180, 182, and 184, which can provide electrical connections between integrated circuit 100 and an external device (e.g., a power source) on PCB 176. Package substrate 106 can also include a solder resist layer 190 on surface 150 to shield metal interconnects in the package substrate (e.g., metal interconnects 170, 172, and 174) from the solder balls.

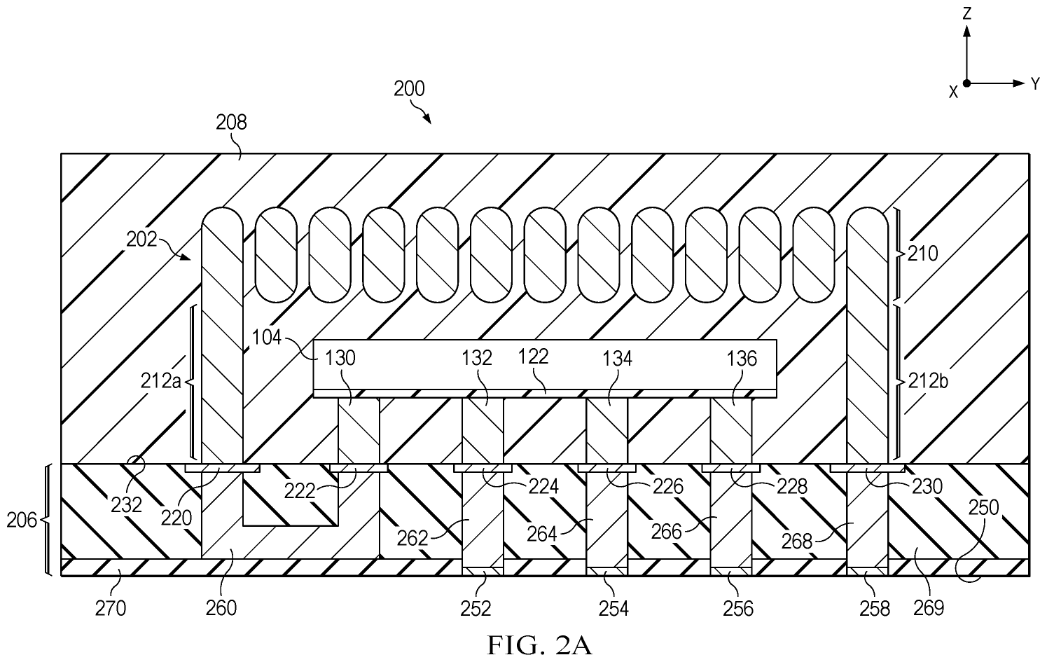

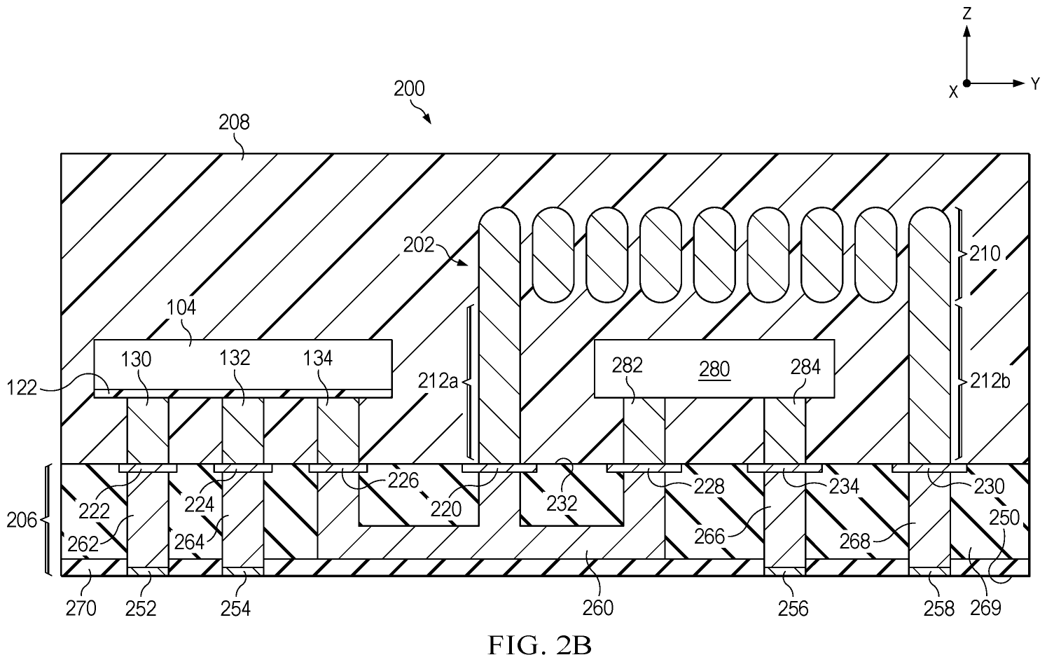

FIG. 2A illustrates an example of integrated circuit 200 that can have a reduced footprint compared with integrated circuit 100 of FIGS. 1A and 1B. FIG. 2A illustrates a side view of integrated circuit 200. Referring to FIG. 2A, integrated circuit 200 can include an inductor 202 and semiconductor die 104 mounted to package substrate 206. Integrated circuit 200 can also include a magnetic material (e.g., MMC) on package substrate 206. The magnetic material can encapsulate inductor 202 and semiconductor die 104 as an encapsulation package 208. In some examples, package substrate 206 can include a routable lead frame (RLF). Inductor 202 can include a coil portion 210, which can include various types of cores such as a ferrite core and a metal particle core, and stilt portions 212a and 212b that support coil portion 210 over package substrate 206. Also, semiconductor die 104 can be positioned between stilt portions 212a and 212b and underneath coil portion 210, so that coil portion 210 and semiconductor die 104 can form a device stack. In some examples, coil portion 210 can have openings facing sideways (e.g., along the x/y axes), as shown in FIGS. 3A-3C. In some examples, coil portion 210 can have openings facing up/down over semiconductor die 104 (e.g., along the z-axis), as shown in FIGS. 4A-4C.

Package substrate 206 can include metal pads 220, 222, 224, 226, 228, and 230, which can be Copper pads, on a surface 232 on which inductor 202 and semiconductor die 104 are attached. Integrated circuit 200 can include metal interconnects 130, 132, 134, and 136 of semiconductor die 104 can be coupled to respective metal pads 222, 224, 226, and 228 via a solder layer. Also, stilts 212a and 212b of inductor 202 can be coupled to respective metal pads 220 and 230 via a solder layer.

Package substrate 206 can also include metal pads on a surface 250 opposite to surface 232, such as metal pads 252, 254, 256, and 258 which can include Copper pads or pads made of other metals (e.g., Silver and Palladium). Metal pads 252, 254, 256, and 258 can be coupled to an external device via solder balls, such as PCB 176 and solder balls 180 through 184 of FIG. 1, to provide electrical connections between integrated circuit 200 and the external device. Package substrate 206 can also include metal interconnects, such as Copper interconnects, that connect between the metal pads of the same or different surfaces. For example, package substrate 206 can include a metal interconnect 260 coupled between metal pads 220 and 222 (on surface 232) to provide an electrical connection between inductor 202 and semiconductor die 104. Package substrate 206 can also include a metal interconnect 262 coupled between metal pads 224 and 252, a metal interconnect 264 coupled between metal pads 226 and 254, a metal interconnect 266 coupled between metal pads 228 and 256, and a metal interconnect 268 coupled between metal pads 230 and 258, to provide electrical connections between the external device and inductor 202 and/or semiconductor die 104. Package substrate 206 can include an electrical insulation layer 269, such as a polymer, ABF, or a ceramic material, to provide electrical insulation among the metal interconnects and the metal pads. Also, package substrate 206 can include a solder resist layer 270 below surface 250 to shield metal interconnects in the package substrate (e.g., metal interconnects 260, 262, 264, 266, and 268) from the solder balls and the external device.

Also, as described above, inductor 202 and semiconductor die 104 can be encapsulated in encapsulation package 208 on package substrate 206. Encapsulation package 208 can include a magnetic material such as an MMC. The MMC can have metallic particles (e.g., iron particles) and an insulation material (e.g., a polymer resin) in which the metallic particles are suspended. Encapsulation package 208 can shield inductor 202 and increase the magnetic field density, which can improve the efficiency of inductor 202 in converting between electrical and magnetic energies. The MMC material of encapsulation package 208 can fill the space within inductor 202, such as in the center of coil portion 210 (e.g., if inductor 202 has an air core) and between individual coils of coil portion 210. The MMC material can also fill the space between coil portion 210 and semiconductor die 104, and between metal interconnects 130, 132, 134, and 136.

FIG. 2B illustrates another example of integrated circuit 200. Referring to FIG. 2B, semiconductor die 104 can be positioned outside of and adjacent to inductor 202. Integrated circuit 200 can include another circuit component, such as a capacitor 280, positioned under coil portion 210 and stilt portions 212a and 212b, so that coil portion 210 and capacitor 280 can form a device stack. In some examples, semiconductor die 104 and capacitor 280 can be positioned under coil portion 210 and stilt portions 212a and 212b to form the device stack.

Package substrate 206 can include metal pad 234 (e.g., Copper pad) in addition to metal pads 220 through 230 on surface 232 on which semiconductor die 104 and capacitor 280 are attached. Integrated circuit 200 can include metal interconnects 130, 132, and 136 (e.g., Copper pillars, solder bumps, or UBM interconnects) coupled between semiconductor die 104 and respective metal pads 222, 224, and 226 of package substrate 206. Also, integrated circuit 200 can include metal interconnects 282 and 284 (e.g., Copper pillars, solder bumps, or UBM interconnects) coupled between capacitor 280 and respective metal pads 228 and 234. Package substrate 206 can also include metal interconnects coupled between metal pads on surface 232 and on surface 250 to provide external access to semiconductor die 104, inductor 202, and capacitor 280. For example, package substrate 206 can include metal interconnect 262 coupled between metal pads 222 and 252, metal interconnect 264 coupled between metal pads 224 and 254, metal interconnect 266 coupled between metal pads 228 and 256, and metal interconnect 268 coupled between metal pads 230 and 258. Package substrate 206 can also include metal interconnect 260 coupled among metal pads 220, 226, and 228 to provide an internal electrical connection among semiconductor die 104, inductor 202, and capacitor 280.

By placing semiconductor die 104 and/or capacitor 280 below coil portion 210 of inductor 202, integrated circuit 200 of FIG. 2A and FIG. 2B can have a reduced footprint (e.g., on the x-y plane), which can also shorten the metal interconnects between semiconductor die 104 and inductor 202 (e.g., metal interconnect 260) and reduce their parasitic capacitances. The arrangements of FIG. 2A and FIG. 2B also allow the coil portion of the inductor to cover most of the footprint of integrated circuit 200, and a larger inductor with increased inductance can be included in integrated circuit 200. Also, by encapsulating inductor 202 in an MMC encapsulation package, the magnetic field density within integrated circuit 200 can be increased, which can improve the efficiency of inductor 202 in converting between electrical and magnetic energies.

Integrated circuit 200 can be fabricated by mounting multiple electronic components (e.g., semiconductor dies 104, inductors 202 and/or capacitors 280) to a substrate, depositing an MMC material onto the electronic components and the substrate, molding and hardening the MMC material to form an encapsulation package, and then dicing the molded and hardened MMC material and the substrate into multiple integrated circuits 200, such that each integrated circuit 200 can include a set of electronic components (e.g., a semiconductor die 104, an inductor 202 and/or a capacitor 280) mounted to substrate 206 and encapsulated by MMC encapsulation package 208.

While the MMC encapsulation package can increase magnetic field density within integrated circuit 200, the dicing operation can change the structure of the MMC material on the diced surface and reduce the electrical breakdown voltage through the MMC material. Because of the reduced electrical breakdown voltage, a relatively small voltage difference between the metal interconnects can be sufficient for leakage current to flow between the metal interconnects through the MMC material, which can increase the risk of electrical shorts. Accordingly, the functionality, reliability, and safety of integrated circuit 200 can become compromised.

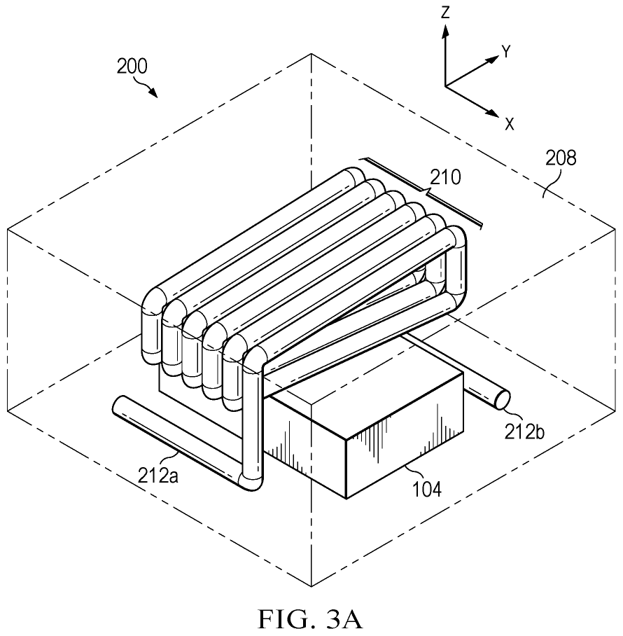

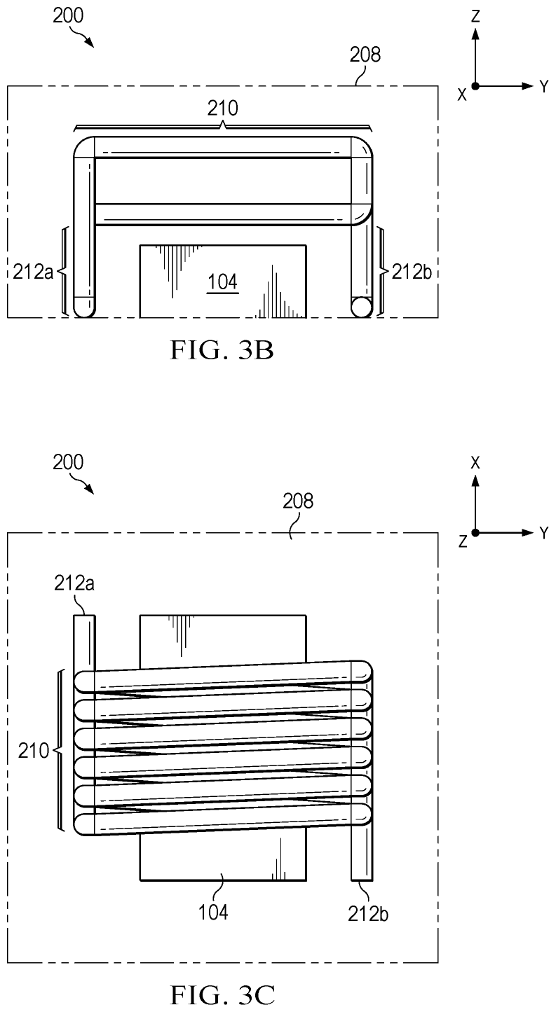

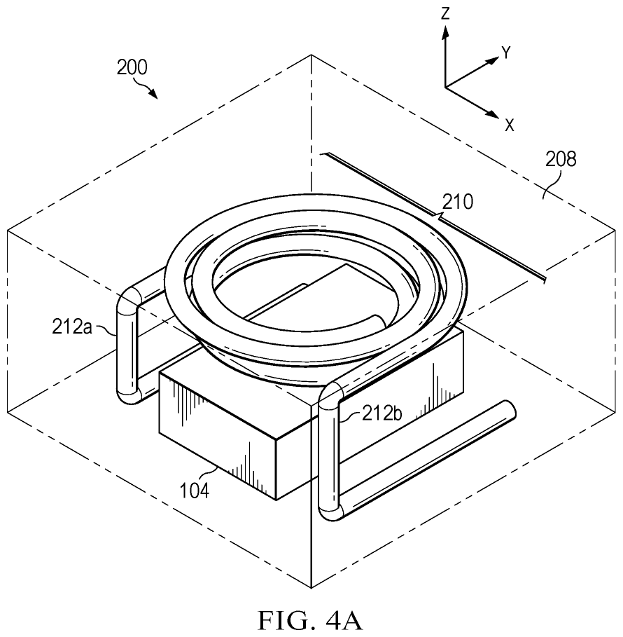

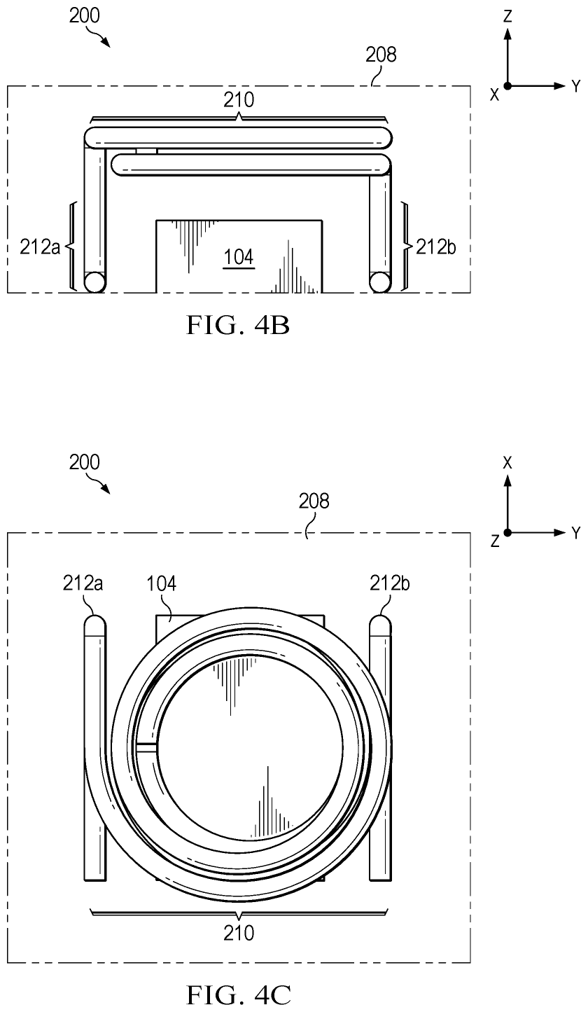

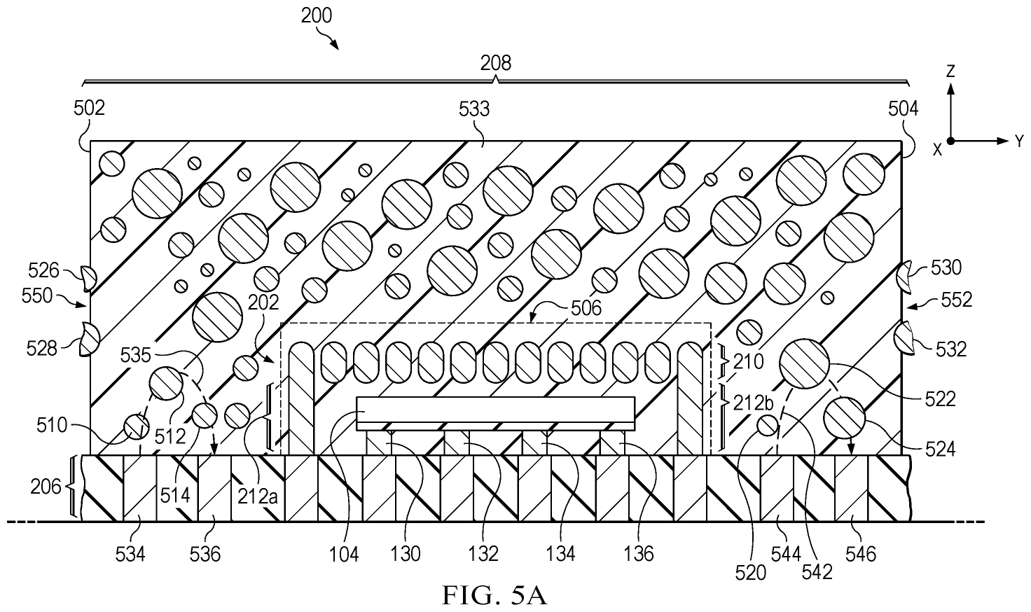

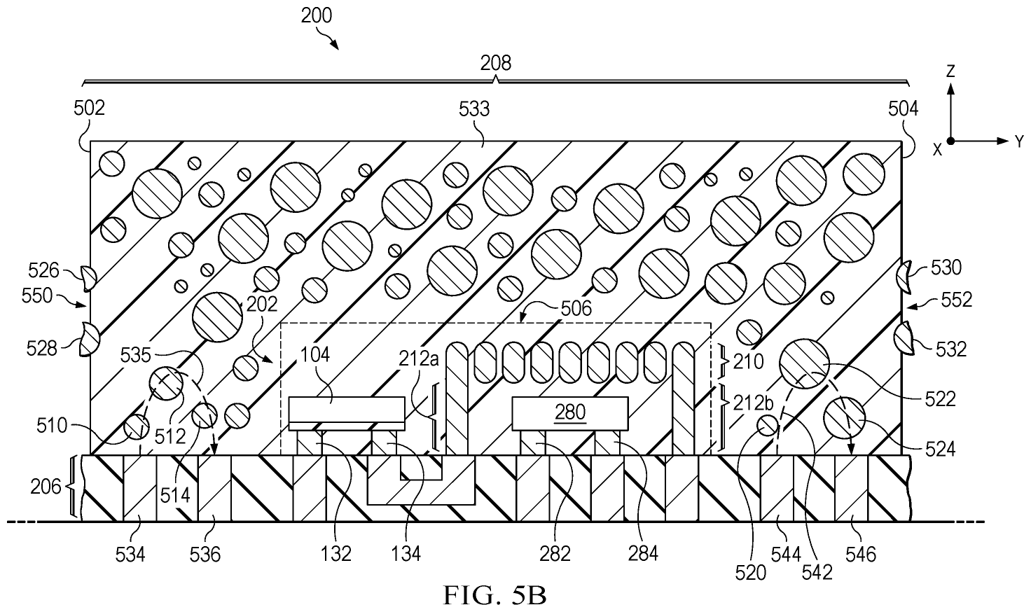

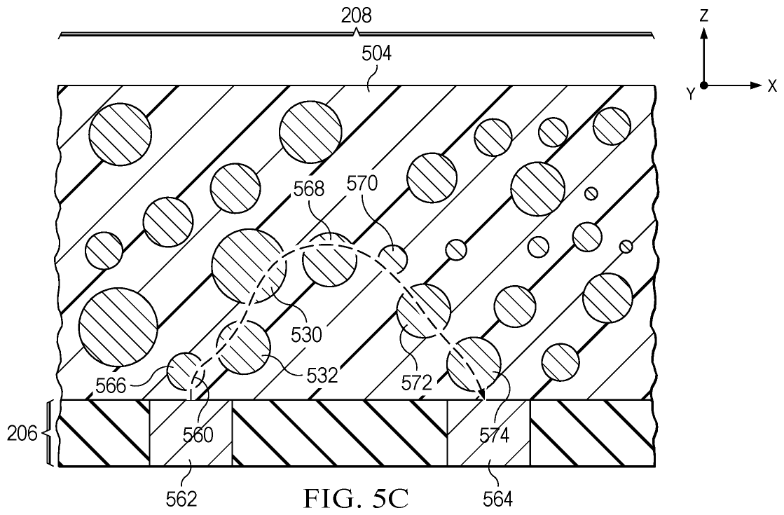

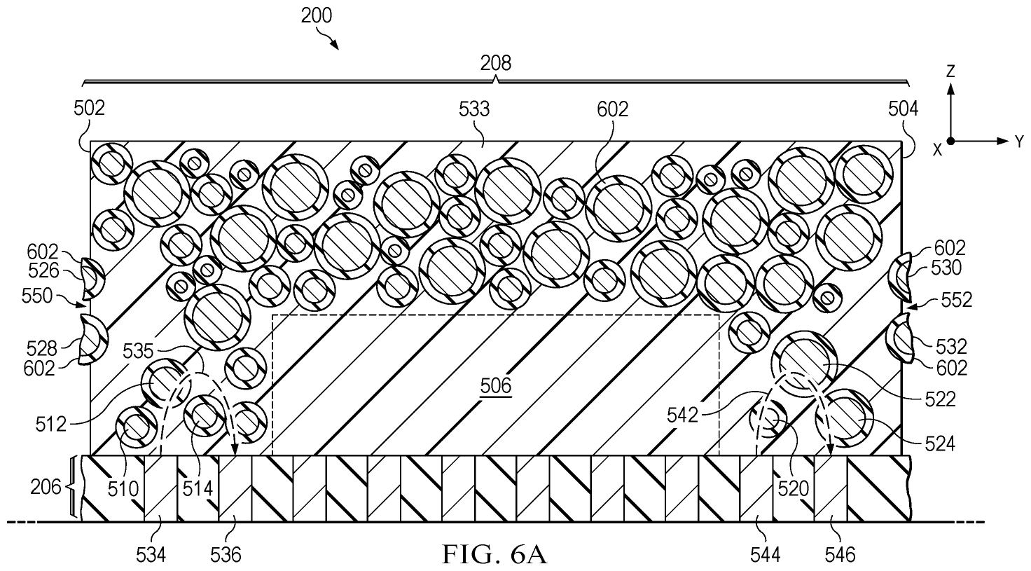

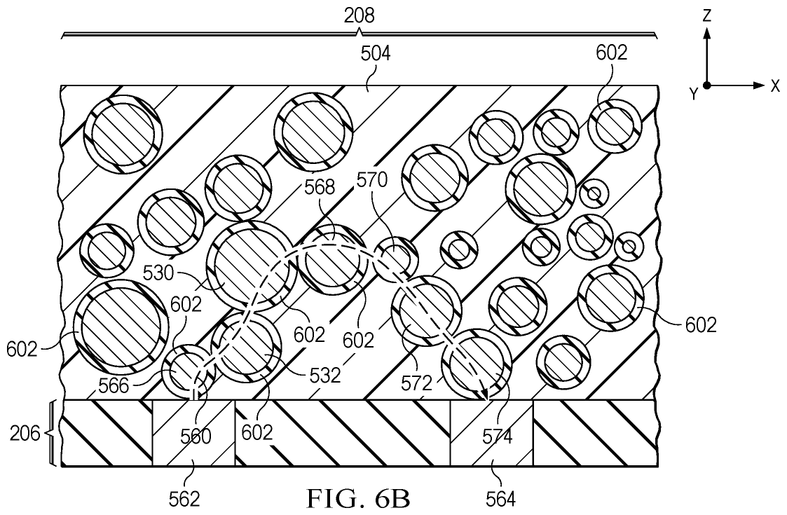

FIGS. 5A through 5C are schematic diagrams that illustrate example structure of the MMC material of encapsulation package 208 of integrated circuit 200. FIG. 5A and FIG. 5B illustrates a first view of MMC encapsulation package 208 and substrate 206 from the x-axis, where diced surfaces 502 and 504 are on the x-z plane. Also, FIG. 5C illustrates a second view of MMC encapsulation package 208 and substrate 206 of FIG. 5A or FIG. 5B from the y-axis and including diced surface 502. MMC encapsulation package 208 and substrate 206 can encapsulate electronic devices 506. In the example of FIG. 5A, electronic devices 506 can include semiconductor die 104, inductor 202, and metal interconnects 130 through 136 of FIG. 2A, with semiconductor die 104 positioned between stilt portions 212a and 212b and below coil portion 210 of inductor 202. In the example of FIG. 5B, electronic devices 506 can include semiconductor die 104, inductor 202, capacitor 280, and metal interconnects 132, 134, 282, and 284 of FIG. 2B, with capacitor 280 positioned between stilt portions 212a and 212b and below coil portion 210 of inductor 202, and semiconductor die 104 positioned adjacent to inductor 202. In subsequent figure FIG. 6A, electronic devices 506 are represented by a dotted line box for brevity.

Referring to FIG. 5A through FIG. 5C, the MMC material of encapsulation package 208 can include metal particles (e.g., iron particles), such as metal particles 510, 512, 514, 520, 522, 524, 526, 528, 530, and 532, suspended in Epoxy resin 533. In FIG. 5A, metal particles 510, 512, 514, 520, 522, and 524 are separated by the Epoxy resin, which can reduce the electrical leakage (and increase the resistance) through the metal particles. For example, there can be a leakage current path 535 between metal interconnects 534 and 536 through metal particles 510, 512, and 514, and a leakage current path 542 between metal interconnects 544 and 546 through metal particles 520, 522, and 524. But because the metal particles are separated by the Epoxy resin, which has a relatively high breakdown voltage (e.g., compared with air), both leakage current path can have high resistance, and very little leakage current can flow between the metal interconnects through the metal particles and the Epoxy resin.

However, the dicing operation may remove some of the resin on diced surfaces 502 and 504, which may expose the metal particles on the diced surfaces and reduce the resistance of the leakage current path through those metal particles. For example, metal particles 526 and 528 on diced surface 502 and metal particles 530 and 532 on diced surface 504 may be exposed by the removal of Epoxy resin 533. Accordingly, part of metal particles 526 and 528 can be separated by an air gap 550, and part of metal particles 530 and 532 can be separated by an air gap 552. Because the air can have a lower breakdown voltage than the Epoxy resin, the metal particles exposed on the diced surfaces 502/504 can provide a leakage current path with reduced resistance. For example, referring to FIG. 5C, there can be a leakage current path 560 with reduced resistance between metal interconnects 562 and 564 and through metal particles 566, 532, 530, 568, 570, 572, and 574 and the air gaps between those metal particles, leading to potential electrical shorts and compromising the functionality, reliability, and safety of integrated circuit 200.

FIG. 6A and FIG. 6B illustrate example MMC materials that can address at least some of the issues described above. Referring to FIG. 6A and FIG. 6B, some or all of the metal particles of the MMC material can be coated metal particles, which are coated with an insulation layer 602, and the coated metal particles are suspended in Epoxy resin 533. Insulation layer 602 can include a material that has a high breakdown voltage, such as Silicon Dioxide (e.g., glass) or a metallic Phosphate (e.g., iron phosphate). Insulation layer 602 can provide electrical insulation, which can add to the electrical insulation provided by Epoxy resin 533 and increase the breakdown voltage of the MMC material. Also, for metal particles exposed on diced surfaces 502 and 504 and separated by air gaps (e.g., metal particles 526, 528, 530, and 532), insulation layer 602 can also add to the electrical insulation provide by the air gaps. Accordingly, a leakage current path through the exposed metal particles, such as leakage current path 560 between metal interconnects 562 and 564 in FIG. 6B, can have a high resistance, which can reduce potential electrical shorts and improve the functionality, reliability, and safety of integrated circuit 200.

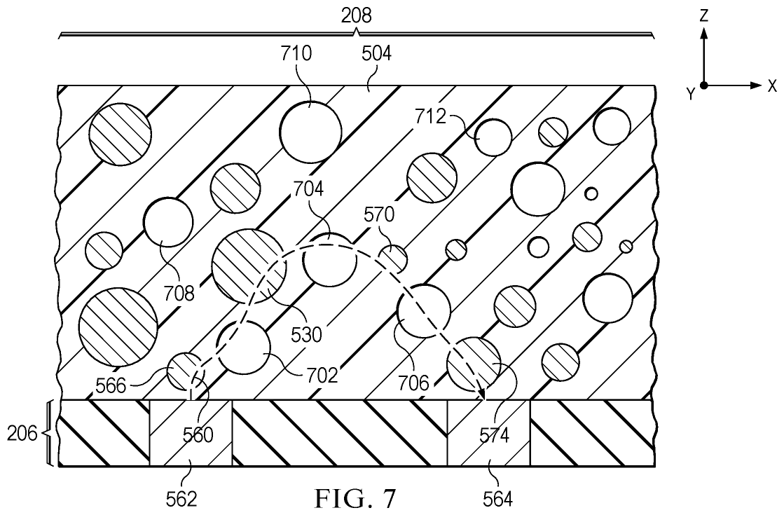

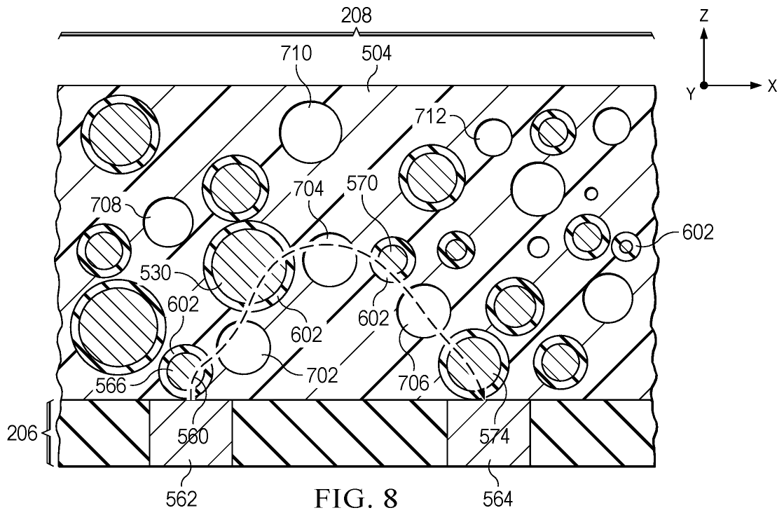

FIG. 7 and FIG. 8 illustrate additional example MMC materials that can reduce leakage along the diced surface. Referring to FIG. 7, some of the metal particles of the MMC material on a diced surface (e.g., diced surface 504) can be removed to create cavities, such as cavities 702, 704, 706, 708, 710, and 712, between the remaining metal particles. The cavities can be filled with an insulation material (e.g., air, or Epoxy resin) to provide additional electrical insulation between the metal particles, which can increase the breakdown voltage and the resistance of current leakage paths through the metal particles. For example, cavity 702 can be along leakage current path 560 between metal particles 566 and 530, cavity 704 can be along leakage current path 560 between metal particles 530 and 570, and cavity 706 can be along leakage current path 560 between metal particles 570 and 574. The insulation material in cavities 702, 704, and 706 can increase the resistance of leakage current path 560 and reduce the amount of leakage current between metal interconnects 562 and 564. Also, as shown in FIG. 8, at least some of the metal particles that remain on diced surface, such as metal particles 530, 566, 570, and 574, can each be coated with insulation layer 602, which can further increase the breakdown voltage of the MMC material and reduce potential electrical shorts.

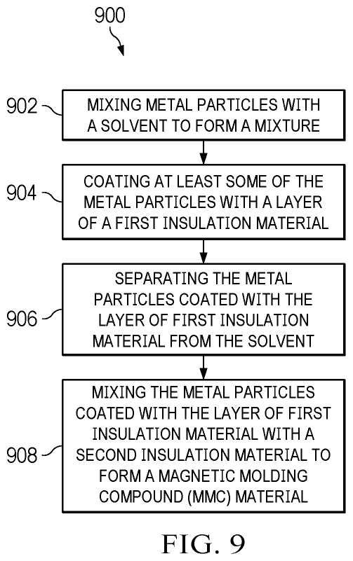

FIG. 9 and FIG. 10 illustrate examples of a method of creating the example MMC material of FIG. 6A and FIG. 6B. FIG. 9 illustrates a flowchart 900 of an example method of creating the MMC material, and FIG. 10 are schematic diagrams illustrating some of the operations of the example method of FIG. 9.

Referring to FIG. 9, in operation 902, metal particles (e.g., iron particles) can be mixed with a solvent to form a mixture. Referring to FIG. 10, in sub-operation 902a, metal particles 1002 can be added to a solvent 1004, such as water or an organic solvent (e.g., alcohol, and kerosene), and then in sub-operation 902b, metal particles 1002 and solvent 1004 can be mixed and stirred to become a viscous slurry 1006, in which metal particles 1002 can be suspended in solvent 1004.

In operation 904, at least some of the metal particles can be coated with a layer of a first insulation material (e.g., insulation layer 602). Examples of the first insulation material can include silicon dioxide and phosphate. Referring again to FIG. 10, in sub-operation 904a, a reagent 1008 can be added to slurry 1007, followed by sub-operation 904b where reagent 1008 and slurry 1006 can be heated (e.g., by a heater 1010) and stirred to form the insulation layer.

In some examples, reagent 1008 can create X—OH or X—OR bond to coat an insulation layer on the surface of metal particles 1002, where X represents Si (silicon) or P (phosphorus), OH represents Hydroxide, and R represents an alkyl substituent. Different reagents 1008 can be used to coat different insulation materials on metal particles 1002. For example, to coat a layer of silicon dioxide on metal particles 1002, a reagent including an orthosilicate, such as tetraethyl orthosilicate (Si(OC₂H₅)₄), can be used in operation 904. Also, to coat a layer of phosphate on metal particles 1002, a reagent including a phosphoric acid, such as orthophosphoric acid (H₃PO₄), can be used in operation 904.

In operation 906, the metal particles coated with the insulation layer can be separated from the solvent. The separation can be performed by, for example, passing slurry 1006 through a filter to remove solvent 1004 and reagent 1008 while retaining the metal particles, followed by washing and drying the metal particles.

In operation 906, the metal particles coated with the insulation layer can be mixed with a second insulation material to form a magnetic molding compound (MMC) material. The second insulation material can include Epoxy resin. As part of operation 906, the metal particles can be mixed with Epoxy resin, followed by a kneading operation in which the mixture can be kneaded with an extruder. The kneaded mixture can be made into a particular shape (e.g., a sheet) and cooled. The MMC material can then be crushed into particles, which can be melted and molded to form encapsulation package 208.

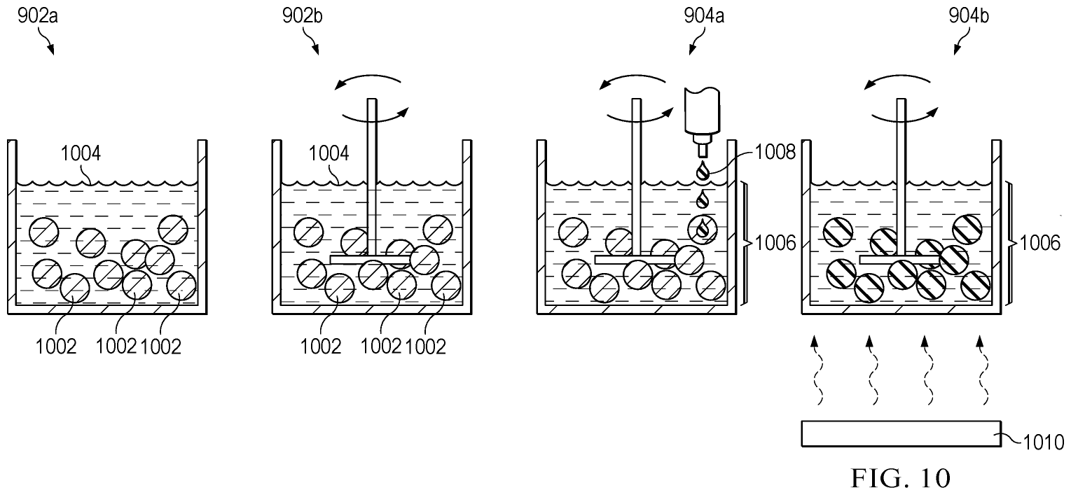

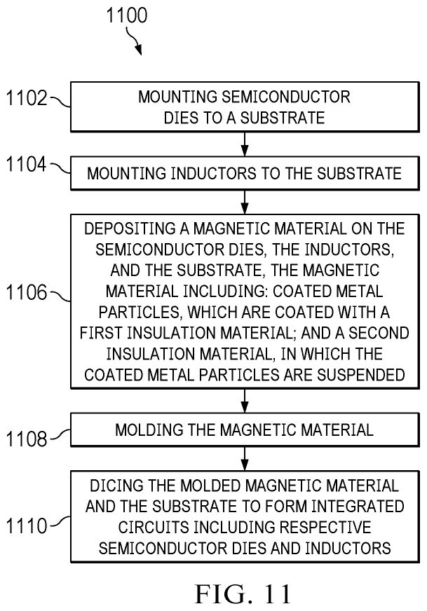

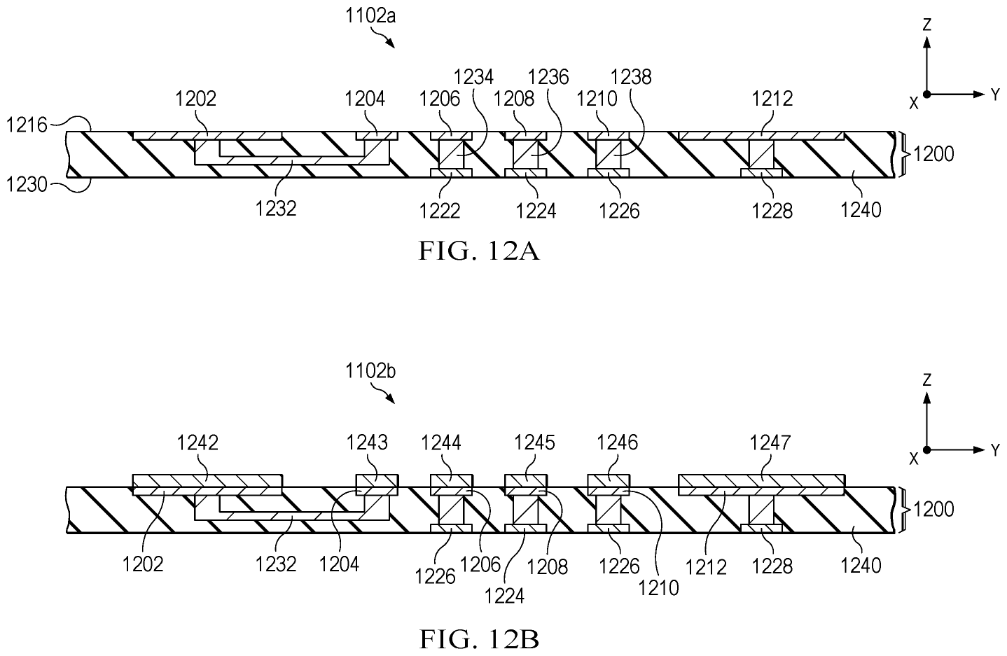

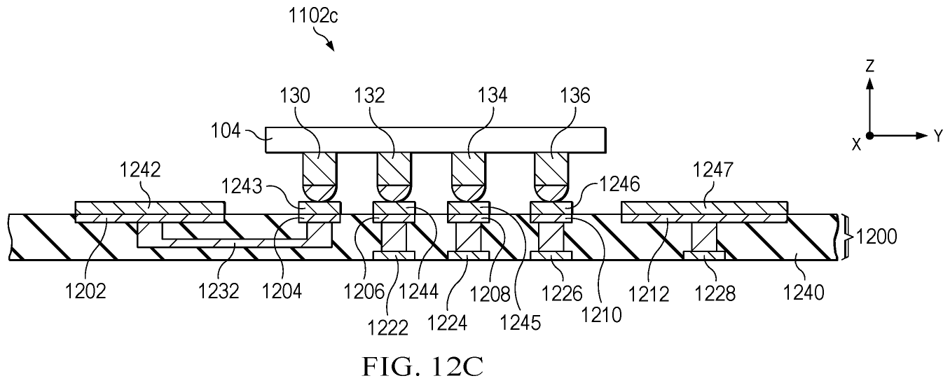

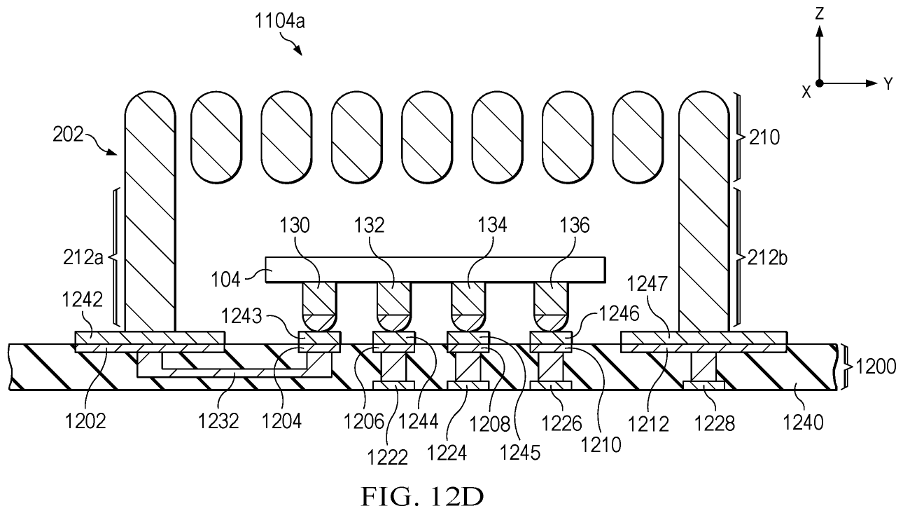

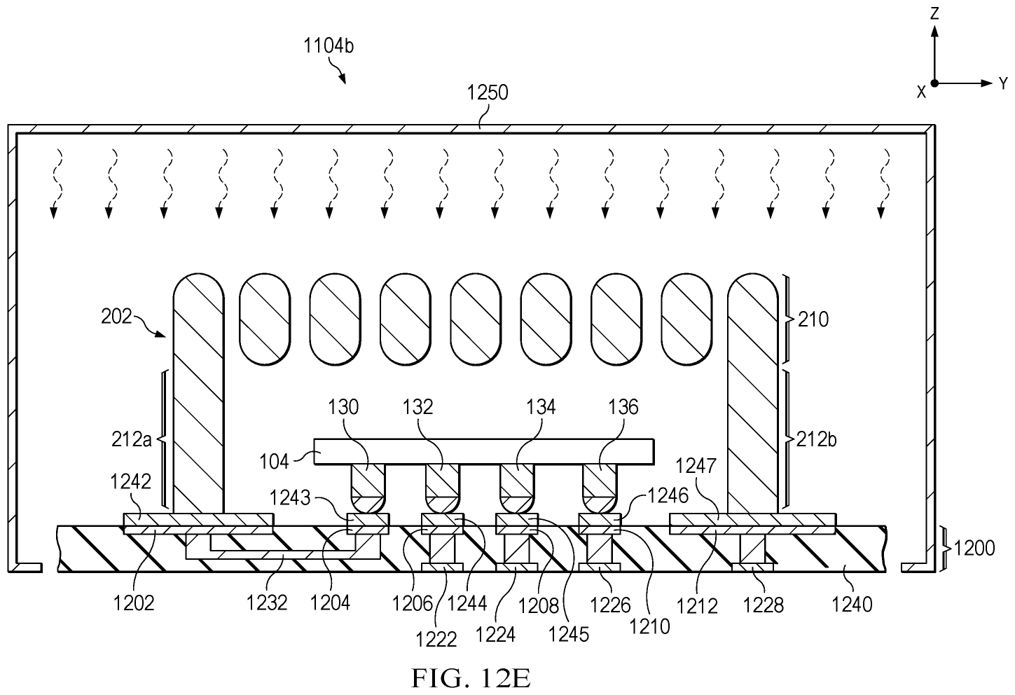

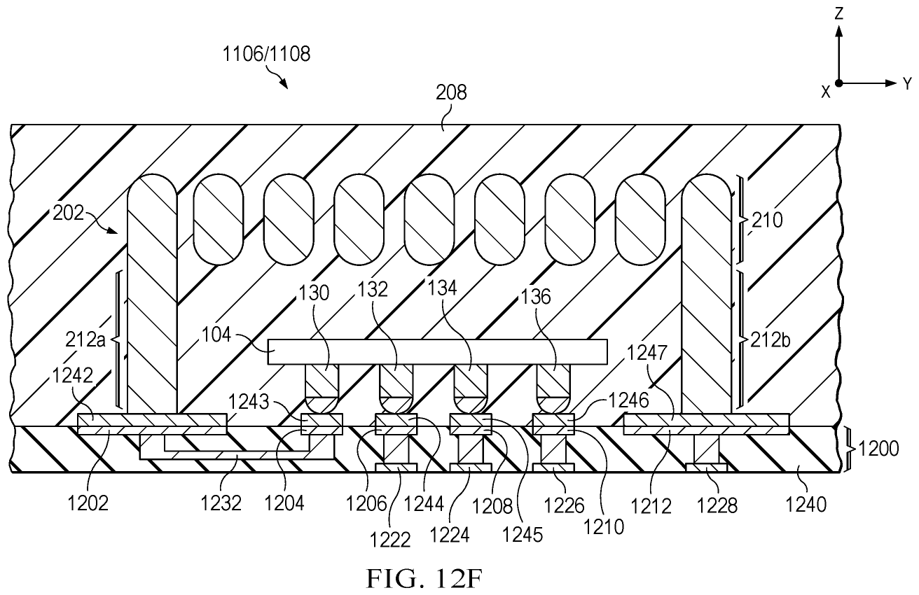

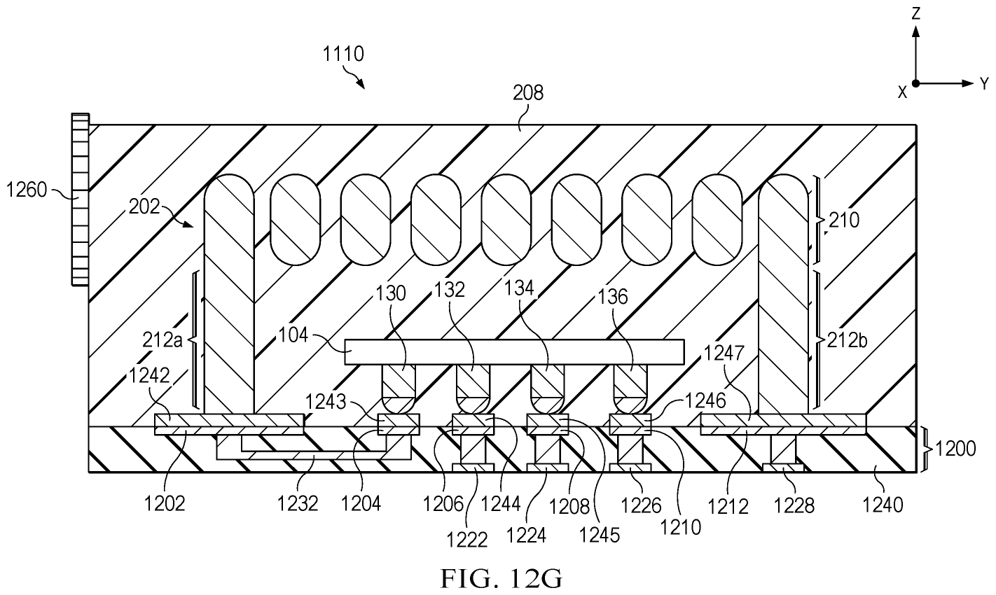

FIG. 11, and FIGS. 12A through 12G illustrate examples of a method of fabricating an integrated circuit with an inductor in a magnetic package, such as integrated circuit 200 of FIGS. 2A through 8. FIG. 11 illustrates a flowchart 1100 of an example method of fabricating the integrated circuit, and FIGS. 12A through 12C are schematic diagrams illustrating various operations of the example method of FIG. 11.

In operation 1102, multiple semiconductor dies can be mounted on a substrate.

Referring to FIG. 12A, in sub-operation 1102a, a substrate 1200 can include metal pads 1202, 1204, 1206, 1208, 1210, 1212 on surface 1216 and metal pads 1222, 1224, 1226, and 1228 on surface 1230 opposite to surface 1216. Substrate 1200 can also include metal interconnects 1232, 1234, 1236, and 1238 to provide electrical connection between the metal pads. Substrate 1200 can also include an insulation layer 1240, such as a polymer, ABF, or a ceramic material, to provide electrical insulation among the metal interconnects and the metal pads. In some examples, substrate 1200 can include a routable lead frame (RLF).

Also, referring to FIG. 12B, in sub-operation 1102b, solder layers 1242, 1243, 1244, 1245, 1246, and 1247 are deposited on respective metal pads 1202, 1204, 1208, 1210, and 1212.

Further, referring to FIG. 12C, in sub-operation 1102c, semiconductor dies 104 can be mounted to metal pads 1234 through 1246 of substrate 1200 via metal interconnects 130 through 136. In some examples, a pick-and-place (PnP) machine can align metal interconnects 130 through 136 with respective solder layers 1243 through 1246, and then place semiconductor dies 104 onto the solder layers.

Referring again to FIG. 11, in operation 1104, multiple inductors can be mounted on the substrate.

Referring to FIG. 12D, in sub-operation 1104a, stilt portions 212a and 212b of inductor 202 can be mounted to metal pads 1202 and 1212 of substrate 1200 via respective solder layers 1242 and 1247, such that coil portion 210 of inductor 202 is on/over semiconductor die 104. In some examples, a PnP machine can align stilt portions 212a and 212b of inductor 202 with respective solder layers 1242 and 1247, and then place the stilt portions onto the solder layers. Also, referring to FIG. 12E, in sub-operation 1104b, a reflow operation can be performed, in which inductors 202 and semiconductor dies 104, together with substrate 1200 and the solder layers 1242 through 1247, are heated in an oven 1250. The solder layers can reflow in a molten state to create solder joints between inductors 202 and semiconductor dies 104 and substrate 1200.

Referring to FIG. 11 and FIG. 12F, in operation 1106, a magnetic material (e.g., MMC) is deposited on the semiconductor dies, the inductors, and the substrate. The magnetic material includes coated metal particles, which are coated with a first insulation material; and a second insulation material, in which the coated metal particles are suspended. Example of the magnetic material are illustrated in FIGS. 6A through 8. The magnetic material can include coated metal particles, such as metal particles 510, 512, 514, 520, 522, and 524 of FIGS. 6A through 8, where each coated metal particle is coated with insulation layer 602 such as silicon dioxide/phosphate layer, and the coated metal particles are suspended in Epoxy resin, to reduce leakage on the diced surface where the Epoxy resin may be removed and metal particles may be exposed. Also, in operation 1108, the magnetic material can be molded and heated, such that the magnetic material can be hardened to form encapsulation package 208 for respective semiconductor dies 104 and inductors 202.

Referring to FIG. 12G, in operation 1110, the molded magnetic material and the substrate can be diced to form integrated circuits including respective semiconductor dies and inductors. The dicing can be performed by, for example, a rotary blade 1260.

In some examples, the dicing can be performed to remove some of the metal particles from the magnetic material to create cavities, which can be filled with air or another insulation material such as Epoxy resin. Removal of metal particles can be performed by increasing the contact time between the metal particles and the blade during the dicing operation. The contact time can be increased by decreasing the speed at which the blade moves across the dicing surface (e.g., the dicing speed), decreasing the rotation speed of the blade (e.g., the spindle speed), or both, so that the force exerted by the blade on the metal particles can overcome the bonding force between the metal particles and the Epoxy resin.

Also, as described above the cavities can be filled with air or another insulation material, such as Epoxy resin. After the dicing operation, a resin coating layer can be applied on the dicing surface to fill the cavities with resin. In some examples, the resin coating layer can be applied by a spray or by a spin coating operation.

Any of the methods described herein may be totally or partially performed with a computing system including one or more processors, which can be configured to perform the steps. Thus, embodiments can be directed to computing systems configured to perform the steps of any of the methods described herein, potentially with different components performing respective steps or a respective group of steps. Although presented as numbered steps, steps of methods herein can be performed at a same time or in a different order. Additionally, portions of these steps may be used with portions of other steps from other methods. Also, all or portions of a step may be optional. Additionally, any of the steps of any of the methods can be performed with modules, units, circuits, or other means for performing these steps.

In this description, the term “couple” may cover connections, communications or signal paths that enable a functional relationship consistent with this description. For example, if device A provides a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal provided by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described herein as including one or more semiconductor elements (such as transistors), one or more passive elements (such as resistors, capacitors and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end-user and/or a third party.

Certain components may be described herein as being of a particular process technology, but these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in series or in parallel between the same two nodes as the single resistor or capacitor.

Uses of the phrase “ground voltage potential” in this description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

Modifications are possible in the described examples, and other examples are possible, within the scope of the claims.

What is claimed is:

1. An integrated circuit comprising:
a substrate;
a semiconductor die;
metal interconnects, the semiconductor die being mounted to the substrate via the metal interconnects;
an inductor mounted to the substrate; and
a magnetic material encapsulating the semiconductor die, the inductor, and the metal interconnects, the magnetic material including: coated metal particles, which are coated with a first insulation material; and a second insulation material, in which the coated metal particles are suspended.

2. The integrated circuit of claim 1, wherein the second insulation material includes an epoxy resin.

3. The integrated circuit of claim 1, wherein the first insulation material includes a silicon oxide material.

4. The integrated circuit of claim 1, wherein the first insulation material includes a phosphate material.

5. The integrated circuit of claim 1, wherein the magnetic material includes cavities dispersed among at least some of the coated metal particles.

6. The integrated circuit of claim 5, wherein the cavities are filled with air or a third insulation material.

7. The integrated circuit of claim 1, wherein the inductor includes a coil portion and a stilt portion, the stilt portion coupled to the substrate.

8. The integrated circuit of claim 7, wherein the coil portion is over the semiconductor die.

9. The integrated circuit of claim 7, further comprising a capacitor encapsulated in magnetic material,
wherein the coil portion is over the capacitor.

10. The integrated circuit of claim 1, wherein the metal interconnects are first metal interconnects, and the substrate includes:
first metal pads on a first side of the substrate, the first metal pads coupled to the first metal interconnects and to the inductor;
second metal pads on a second side of the substrate opposite to the first side;
an insulation layer between the first side and the second side; and
second metal interconnects in the insulation layer and coupled between the first metal pads and the second metal pads.

11. The integrated circuit of claim 10, wherein:
the first metal pads and the second metal interconnects include a Copper metal;
the second metal pads include at least one of a Palladium metal or a Silver metal; and
the insulation layer includes at least one of: a polymer material, an Ajinomoto Build-up Film, or a ceramic material.

12. The integrated circuit of claim 11, further comprising a solder resist layer on the second side.

13. A method comprising:
mounting semiconductor dies to a substrate;
mounting inductors to the substrate;
depositing a magnetic material on the semiconductor dies and the inductors, the magnetic material including: coated metal particles, which are coated with a first insulation material; and a second insulation material, in which the coated metal particles are suspended;
molding the magnetic material; and
dicing the magnetic material and the substrate to form integrated circuits including respective semiconductor dies and inductors.

14. The method of claim 13, wherein the mixture is a first mixture, and the method further comprises:
mixing the metal particles with a solvent to form a mixture;
adding a reagent to the mixture to coat the metal particles with the first insulation material;
separating the coated metal particles from the solvent; and
mixing the coated metal particles with the second insulation material.

15. The method of claim 14, wherein the reagent includes at least one of: an orthosilicate reagent, or a phosphoric acid.

16. The method of claim 14, further comprising removing at least some of the coated metal particles from a diced surface of the magnetic material.

17. The method of claim 16, wherein the at least some of the coated metal particles are removed from the diced surface during the dicing of the magnetic material.

18. The method of claim 13, wherein the second insulation material includes an epoxy resin.

19. The method of claim 13, wherein the first insulation material includes a silicon oxide material.

20. The method of claim 13, wherein the first insulation material includes a phosphate material.
